(19) United States
(12) Patent Application Publication
(10) Pub. No.: US 2004/0058519 A1
(43) Pub. Date: Mar. 25, 2004

(54) Method for forming bit line contact

(75) Inventors: Kuo-Chien Wu, Kueishan (TW); Yi-Nan Chen, Kueishan (TW)

Correspondence Address: NIXON PEABODY, LLP, 401 9TH STREET, NW, SUITE 900, WASINGTON, DC, 20004-2128, US

(73) Assignee: NANYA TECHNOLOGY CORP., Kueishan (TW)

(21) Appl. No.: 10/329,517

(22) Filed: Dec. 27, 2002

(30) Foreign Application Priority Data
Sep. 25, 2002 (TW) 091122078

(51) Int. Cl. H01L 21/44

(52) U.S. Cl. 438/597

(57) ABSTRACT

A method for forming a bit line contact, which electrically couples to a contact region of a substrate, is provided. The method includes the step of forming an opening in the substrate to expose the contact region. A polysilicon layer is formed in a portion of the opening to electrically couple to the contact region. Then, ions are implanted into the polysilicon layer to transform an upper portion of the polysilicon layer to an amorphous layer. Next, a conductive layer is formed on the amorphous layer.

### CROSS REFERENCE TO RELATED APPLICATIONS

This application claims priority to Taiwan Patent Application No. 091122078 entitled “Method for Forming Bit Line Contact”, filed Sep. 25, 2002.

### FIELD OF INVENTION

The present invention generally relates to a method for forming a contact in a semiconductor device, and more particularly, to a method for forming a bit line contact.

### BACKGROUND OF THE INVENTION

The fabrication of semiconductor devices generally repeatedly performs a series of processes including lithography, etch, deposition, doping, etc on a semiconductor wafer to form layer-stacked integrated circuits. Therefore, the formation of electrical contacts or connections between every layer is one of important processes during the fabrication of integrated circuit devices. As the device size shrinks and the integrated density increases, however, the process window and the test limit become more and more rigorous, which particularly seriously influence the formation of contacts.

Conventionally, aluminum or aluminum alloy are materials for contacts. The solid solubility between the aluminum and silicon, however, is high enough to cause aluminum from the contact migrating to the silicon substrate causing the spiking problem, which induces a short to the substrate and causes the device to fail. Thus, the tungsten plug technique is provided to solve problems induced by the high solid solubility between the aluminum and the silicon layer. The tungsten plug formation process relieves the spiking problem, but has proven problematic for other reasons, however, and these problems are heightened by continuous miniaturization of the integrated circuit and the “stacked” structure of the device.

Referring to FIG. 1, a conventional semiconductor structure 10 including a substrate 12 and a dielectric layer 14 thereon is illustrated. A contact, such as a bit line contact, is formed in the dielectric layer 14 and electrically couple to a contact region 16. The conventional contact plug includes a polysilicon layer 18, a titanium layer 20, a titanium nitride layer 22, and a tungsten layer 24. The titanium layer 20 serves as a glue layer to enhance the adherence between the tungsten layer 24 and the layer thereunder. The titanium nitride layer 22 serves as a barrier layer, which prevents tungsten from diffusing to other layers. The tungsten layer 26 is typically deposited by chemical vapor deposition in an atmosphere of fluorine, which attacks silicon, creating “warm holes” 26 resulting the increase of resistance. Further, warm holes formed from the reaction can extend through the contact region, thereby shorting the device and causing the device to fail.

Moreover, when a high temperature process is performed, the titanium layer 20 violently reacts with the polysilicon layer 18, which results in the formation of a non-uniform surface of silicide layer. Therefore, the surface of titanium nitride layer 22 is also altered due to changes in volume and stress of the layer thereunder, which increases the difficulty in filling the tungsten layer 24 and creates holes 28 resulting in the increase of resistance. Further, the changes in volume and stress between the titanium nitride layer 22 and the titanium layer 20 can cause the contact to fail at the high accelerated stress test. In order to continue in the process of reducing the device size, however, a method for forming electrical contacts which overcomes problems existing in the art are required.

### OBJECTS AND SUMMARY OF THE INVENTION

One aspect of the present invention is to provide a method for forming a contact in a semiconductor device, which forms a steady and uniform silicide layer to improve the yield and reliability of the semiconductor device.

It is another aspect of the present invention that a method for forming a contact is provided, which employs an ion implantation step to transform a portion of polysilicon layer to an amorphous silicon layer resulting in the reduction of voids generated in a subsequent thermal process. Therefore, the increase of contact resistance is prevented and the inferior electrical contact is improved.

It is a further aspect of the present invention that a method for forming a bit line contact is provided, which employs an ion implantation step to improve the interface between the glue layer and barrier layer and to prevent the formation of warm holes during the tungsten deposition process.

A method for forming a contact, which is electrically coupled to a contact region of a substrate, is provided. The method includes the step of forming an opening in the substrate to expose the contact region. Then, a polysilicon layer is formed in a portion of the opening to electrically couple to the contact region. Ions are implanted into the polysilicon layer to transform an upper portion of the polysilicon layer to an amorphous layer. Next, a conductive layer is formed on the amorphous layer.

The ions are selected from a group consisting of arsenic (As), silicon (Si), germanium (Ge), and the combination thereof. The step of implanting ions includes implanting the ions at about 10 to about 80 KeV and a dose between about 1E14 to about 6E15 atoms/cm². The step of forming the conductive layer includes forming a titanium layer with a thickness of about 100 to about 300 angstroms on the amorphous layer by ion metal plasma (IMP) deposition.

The method further includes the step of annealing the substrate at a temperature of about 600 to about 800° C. such that the conductive layer and the amorphous can react steadily and uniformly to form a silicide layer. The method further includes the step of forming a titanium nitride layer with a thickness of about 50 to about 200 angstroms on the titanium layer by chemical vapor deposition (CVD). The method further includes the step of forming a tungsten layer on the titanium nitride layer to form the contact.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a cross-sectional view of a conventional bit line contact;

FIG. 2 illustrates a cross-sectional view of forming an opening in an exemplary embodiment of the present invention;

FIG. 3 illustrates a cross-sectional view of forming a polysilicon layer in an exemplary embodiment of the present invention;

FIG. 4 illustrates a cross-sectional view of implanting ions to form an amorphous layer in an exemplary embodiment of the present invention;

FIG. 5 illustrates a cross-sectional view of forming a glue layer and a barrier in an exemplary embodiment of the present invention; and

FIG. 6 illustrates a cross-sectional view of forming a bit line contact in an exemplary embodiment of the present invention.

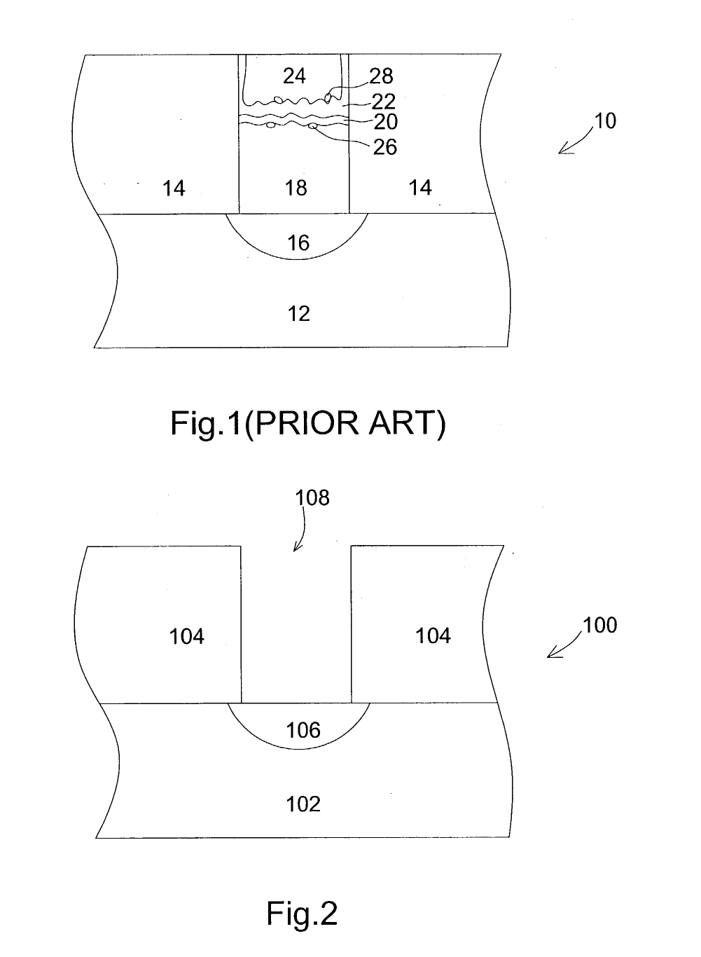

### DETAILED DESCRIPTION OF THE INVENTION

The present invention discloses a method for forming a contact in a semiconductor device to improve the yield and reliability of the device. FIGS. 2 to 6 illustrate a preferred embodiment of the present invention.

Referring to FIG. 2, in an exemplary embodiment of the present invention, the method includes the step of providing a substrate 100, which can be any substrate with a contact region 106 therein. In the exemplary embodiment, the substrate 100 is a semiconductor substrate 102 having an interlayer dielectric layer 104 formed thereon as shown in FIG. 2. For example, the substrate 100 can be a silicon substrate having an oxide layer formed thereon. The semiconductor substrate 102 has a contact region 106, such as a bit line contact region, which serves as an electrical coupling region. Then, an opening 108 is formed in the substrate 100 to expose the contact region 106. The opening 108 can be formed by a conventional lithography technique and an etch process. For example, a patterned photoresist layer (not shown) is first formed on the interlayer dielectric layer 104 to define the opening. Then, the interlayer dielectric layer 104 is etched to expose the contact region 106 by using the patterned photoresist layer as a mask.

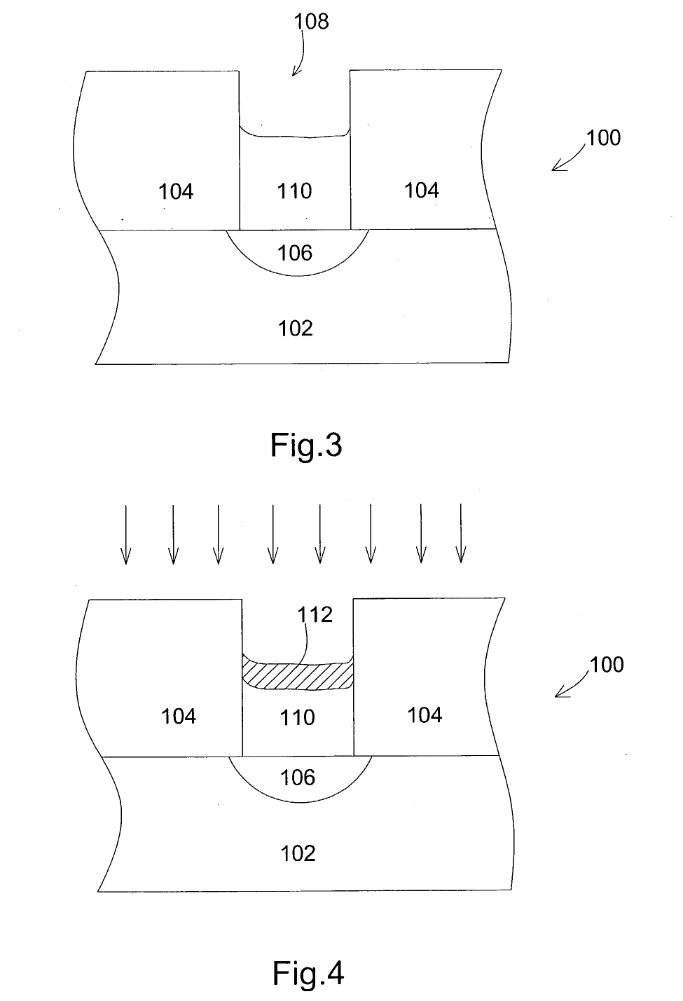

Referring to FIG. 3, a polysilicon layer 110 is formed in a portion of the opening 108 to electrically couple to the contact region 106. The step of forming the polysilicon layer 110 preferably includes the step of forming the polysilicon layer 110 on the substrate 100 to fully fill the opening 108 and to electrically couple to the contact region 106. Then, the polysilicon layer 110 is etched such that the polysilicon layer 110 partially fills the opening 108. In an exemplary embodiment, the polysilicon layer 110 can be formed by chemical vapor deposition technique and then removed by either wet etch or dry etch processes. For example, the polysilicon layer 110 is over-etched or etched back such that the remains of the polysilicon layer 110 fills a portion of the opening 108. In other word, the filling level of the remaining polysilicon layer 110 is lower than the maximum level of the opening 108.

Now referring to FIG. 4, ions are implanted into the polysilicon layer 110 to transform an upper portion of the polysilicon layer 110 into an amorphous layer 112. The ions can be selected from a group consisting of arsenic (As), silicon (Si), germanium (Ge), and the combination thereof. The ions also can be any material, which reacts with silicon to form a silicide. The step of implanting the ions preferably includes implanting ions at about 10 to about 80 KeV and a dose between about 1E14 to about 6E15 atoms/cm².

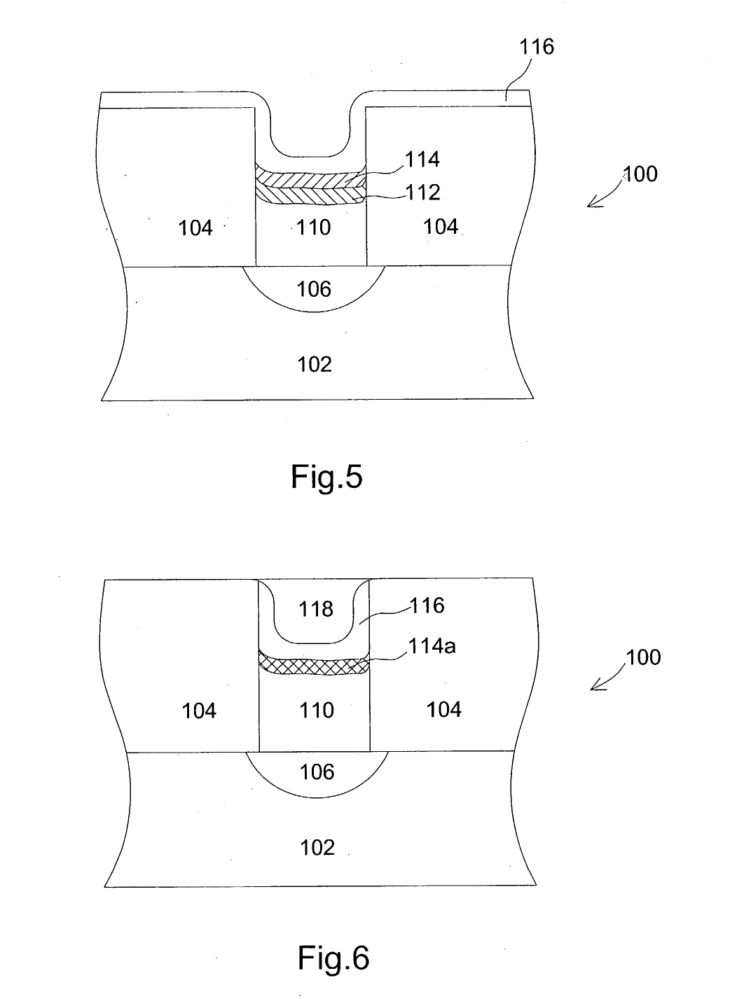

Referring to FIG. 5, a conductive layer 114, such as a titanium layer, is formed on the amorphous layer 112. The titanium layer serves as a glue layer to enhance the adherence between a subsequent layer and the layer thereunder. The step of forming the titanium layer includes forming a titanium layer with a thickness of about 100 to about 300 angstroms by ion metal plasma (IMP) deposition. The titanium layer 114 can also be formed by multi-deposition processes.

Then, a titanium nitride layer 116 is formed on the titanium layer 114. The titanium nitride layer 116 serves as a barrier layer to prevent the internal diffusion of materials from adjoining conductive layer to other layers. The step of forming the titanium nitride layer 116 preferably includes forming a titanium nitride layer 116 with a thickness of about 50 to about 200 angstroms by chemical vapor deposition (CVD). Then, the substrate 100 is annealed at a temperature of about 600 to about 800° C. such that the titanium layer 114 steadily and uniformly reacts with the amorphous silicon layer 112 thereunder to form a silicide layer 114a, such as titanium silicide layer. Then, a tungsten layer 118 is formed on the titanium nitride layer 116 to form the bit line contact, as shown in FIG. 6. The tungsten layer 118 can be formed by chemical vapor deposition and chemical mechanical polishing processes.

It is noted that the present invention employs the ion implantation to transform the upper potion (or surface portion) of the polysilicon layer 110 into the amorphous layer 112 such that the glue layer, titanium layer, can react with silicon in the amorphous layer 112 more steadily and uniformly. Therefore, during the annealing process, the changes in volume and stress of the titanium layer and the titanium nitride layer are minimized. Furthermore, the formation of warm holes in the interface between the polysilicon layer and the titanium layer is reduced during the deposition of the tungsten. The test yield of semiconductor devices of the present invention is improved at the high accelerated stress test (HAST). Particularly, in an experiment of 45 semiconductor devices with improved bit line contacts of the present invention, all 45 semiconductor devices pass the HAST. Moreover, the total production yield can be as high as 90% or higher.

Although specific embodiments have been illustrated and described, it will be obvious to those skilled in the art that various modifications may be made without departing from what is intended to be limited solely by the appended claims.

What is claimed is

1. A method for forming a contact in a semiconductor device, said contact electrically coupling to a contact region of a substrate, comprising:
forming an opening in said substrate to expose said contact region;
forming a polysilicon layer in a portion of said opening to electrically couple to said contact region;
implanting ions into said polysilicon layer to transform an upper portion of said polysilicon layer to an amorphous layer; and
forming a conductive layer on said amorphous layer.

2. The method according to claim 1, wherein said step of forming said polysilicon layer comprises:
forming said polysilicon layer on said substrate to fill said opening; and
etching said polysilicon layer such that said polysilicon layer partially fills said opening.

3. The method according to claim 1, wherein said ions are selected from a group consisting of arsenic (As), silicon (Si), and germanium (Ge).

4. The method according to claim 2, wherein said step of implanting said ions comprises implanting said ions at about 10 to about 80 KeV and a dose between about 1E14 to about 6E15 atoms/cm².

5. The method according to claim 1, wherein said step of forming said conductive layer comprises forming a titanium layer on said amorphous layer.

6. The method according to claim 5, wherein said step of forming said titanium layer comprises forming a titanium layer with a thickness of about 100 to about 300 angstroms by ion metal plasma (IMP) deposition.

7. The method according to claim 5 further comprising forming a titanium nitride layer on said conductive layer.

8. The method according to claim 7, wherein said step of forming said titanium nitride layer comprises forming a titanium nitride layer with a thickness of about 50 to about 200 angstroms by chemical vapor deposition (CVD).

9. The method according to claim 7 further comprising annealing said substrate at a temperature of about 600 to about 800° C.

10. The method according to claim 7 further comprising forming a tungsten layer on said titanium nitride layer to form said contact.

11. A method for forming a bit line contact in a semiconductor device, said bit line contact electrically coupling to a contact region of a substrate, comprising:
forming an opening in said substrate to expose said contact region;
forming a polysilicon layer in a portion of said opening to electrically couple to said contact region;
implanting ions into said polysilicon layer to transform an upper portion of said polysilicon layer to an amorphous layer;
forming a titanium layer on said amorphous layer;
forming a titanium nitride layer on said titanium layer;
annealing said substrate at a temperature of about 600 to about 800° C.; and
forming a tungsten layer on said titanium layer to form said bit line contact.

12. The method according to claim 11, wherein said step of forming said polysilicon layer comprises:
forming said polysilicon layer on said substrate to fill said opening; and
etching said polysilicon layer such that said polysilicon layer partially fills said opening.

13. The method according to claim 11, wherein said ions are selected from a group consisting of arsenic (As), silicon (Si), and germanium (Ge).

14. The method according to claim 13, wherein said step of implanting said ions comprises implanting said ions at about 10 to about 80 KeV and a dose between about 1E14 to about 6E15 atoms/cm².

15. The method according to claim 11, wherein said step of forming said titanium layer comprises forming a titanium layer with a thickness of about 100 to about 300 angstroms by ion metal plasma (IMP) deposition.

16. The method according to claim 11, wherein said step of forming said titanium nitride layer comprises forming a titanium nitride layer with a thickness of about 50 to about 200 angstroms by chemical vapor deposition (CVD).
